(19) United States
(12) Patent Application Publication
(10) Pub. No.: US 2008/0276133 A1
(43) Pub. Date: Nov. 6, 2008

(54) Software-Controlled Dynamic DDR Calibration

(76) Inventors: Andrew Hadley, Colorado Springs, CO (US); Stuart Nuffer, Elbert, CO (US); Adam Browen, Colorado Springs, CO (US)

Correspondence Address: LSI CORPORATION, 1621 BARBER LANE, MS: D-105, MILPITAS, CA, 95035, US

(21) Appl. No.: 11/743,599

(22) Filed: May 2, 2007

(51) Int. Cl. G06F 11/00; G01R 31/3183; G06F 1/12

(52) U.S. Cl. 714/56; 713/400; 714/744

(57) ABSTRACT

A system, device and method are described that provide dynamic calibration of high-speed systems, such as high-speed DDR memory systems. In accordance with certain embodiments of the invention, a DDR controller includes functionality that both initializes settings associated with a data window and dynamically maintains the data window within a defined threshold of operation. In various embodiments, an initial calibration module is provided on the DDR controller for performing a full calibration wherein a data window is initially generated and a center point of the data window is established within a specified threshold. Interrupts may be generated to evaluate the data window and center point and/or recalibrate the data window and center point in response to the evaluation or an interrupt generated from another source, such as a system error or user generated interrupt. If a timer expiration interrupt occurs, the data window and its center point are re-evaluated.

### BACKGROUND

A. Technical Field

This invention relates to memory systems, and more particularly, to devices and methods for providing dynamic calibration and maintenance of a data window and corresponding center point within a double-data rate (hereinafter, “DDR”) system.

B. Background of the Invention

The application and importance of high-speed processor-based electronic systems is well known. Most of these high-speed processors are multi-gigahertz processors that host a large number of high-level and complex applications having high rate signals and corresponding processes. The multi-gigahertz processors may be associated with high-speed system components such as high-speed memory devices. Examples of such high-speed memory devices include double-data rate synchronous dynamic random access memory (hereinafter “DDR SDRAM”). The DDR SDRAM is approximately twice as fast as a single data rate SDRAM running at the same clock speed because a DDR SDRAM transfers data on both the rising and falling edge of a differential clock provided by a DDR controller.

The higher data rate speeds of DDR systems may present issues regarding the timing of the data transfer. Since data is transferred at both the rising edge and falling edge of the clock input, timing requirements of a DDR oftentimes demand a more precise synchronization for both data write and read operations. In many applications, a DDR controller generates internal clock pulses for synchronizing data write operations and reading operations.

A critical feature of high-speed memory systems is the signal timing between data and clock during both read and write operations. Synchronization issues may result in errors while reading data from memory and writing data to memory. Clock and/or control signals may become desynchronized due to physical characteristics of the devices mounted on the board and changes in the environment in which the memory is operating. These changes in working environment of a DDR memory include voltage and temperature changes that generally cause drift in the optimal operating point.

Because of these higher speeds at which DDR memory systems operate, the system functions with a narrow “valid data window” or eye in which data is processed. Failure to properly read or write data within this data window results in errors being generated within the system. In addition, other factors such as jitter and skew due to mismatched board trace lengths may also give rise to errors.

Control settings on certain high-speed components, such as a DDR controller, may need to be re-adjusted to account for changes in temperature or voltage variances that occur over time. In certain prior art systems, a bidirectional data strobe (hereinafter, “DQS”) at the controller is used to capture the data signal at the receiver. The DQS signal is delayed by some fixed amount and is then used as a common sample clock for each of the receivers in typically a byte or 8 bits of data stream. However, due to system offsets and pin-to-pin offsets in the DRAM, one strobe-delay value for the whole byte may not be the ideal amount of strobe-delay for every pin. Furthermore, while manual adjustment of per-bit offsets can yield higher performing memory systems, requiring manual adjustments of these offsets in a production memory system tends to be time consuming.

The above-mentioned solution, which eliminates pin-to-pin timing variation, provides better calibration, but is quite complex and time consuming.

### SUMMARY OF THE INVENTION

The present invention provides systems, devices and methods for dynamically optimizing calibration operations within high-speed systems, such as memory systems and components therein. In various embodiments of the invention, such high-speed memories may include DDR systems such as DDR RAM and DDR SRAM.

In various embodiments of the invention, the DDR memory system may be calibrated by providing various modules capable of providing dynamic calibration of the DDR controller. An initial calibrating module may be provided on the DDR controller for performing a full calibration of a DDR memory system. The full calibration sequence may be performed at a “start of a day” initialization of the DDR controller or at anytime during which the DDR controller is initialized. In certain embodiments of the invention, the full calibration procedure of the DDR controller may include the processes of a standard DDR initialization sequence for obtaining standard configuration settings.

The full calibration of the DDR controller may also include the process of performing a write/read/compare routine to a certain memory range while varying a plurality of allowable configuration settings in the controller. The routine may be performed by generating a ‘test’ pattern and reading/comparing this ‘test’ pattern relative to the configuration settings of the memory. A pass/fail type rating may be designated to each tested setting and a frequency of failure may be tracked.

A collection of passed settings may be used to create an optimal data window. Thus, the optimal data window or the data eye may be determined at the time of initialization and its corresponding center point established. A predefined threshold or threshold range may be used to determine whether the data window and center point are optimized within the DDR memory system. The optimal configuration settings may be saved to non-volatile memory along with a log of the data window abstraction.

In various embodiments, an interrupt is used to initiate a dynamic calibration sequence for the DDR system. Depending on the scenario, the interrupts may be generated by either an error-condition interrupt or a timer expiration interrupt. The error-conditioned interrupt may include a feedback from a temperature sensor, voltage sensor, a signal generated in response to user-interventions, or other appropriate source or trigger.

According to certain embodiments, if an error-condition interrupt (such as temperature feedback or human interventions) occurs, a re-calibration sequence is initiated (or full calibration may also be used). Thus, an error-condition interrupt results in an automatic calibration sequence being performed within a controller.

According to other certain embodiments, if a timer expiration interrupt occurs, the data window and/or its center point are re-evaluated to determine whether re-calibration is appropriate. If this re-evaluation should indicate a potential problem, then a calibration sequence is initiated.

A timer or counter may also be employed that is used to control subsequent real-time calibrations of the DDR system. For example, the timer may be a decreasing counter that expires to a zero count after certain number of counts or programmed amount of time and generates a timer expiration interrupt. In various embodiments of the invention, the timer expiration interrupt occurs when the programmed amount of time expires. This expiration of timer counts gives an indication that an analysis should occur of the data window and center point corresponding to the current DDR configuration settings. This analysis allows for relatively quick identification of a problem or looming problem within the DDR memory system. If appropriate, a re-calibration procedure is performed if the data window and/or center point has “slipped” from its optimal setting.

In certain embodiments, the analyzed data window is compared to a threshold or threshold range to determine whether the data window and the center point have sufficiently deteriorated so the re-calibration is warranted. This re-calibration results in new control parameters which improve the condition of the data window. However, if the current data window and center point is found to be within an acceptable range, then a re-calibration process is not initiated and a timer is restarted to determine the next time in which a data window analysis is to occur.

Other objects, features and advantages of the invention will be apparent from the drawings, and from the detailed description that follows below.

### BRIEF DESCRIPTION OF THE DRAWINGS

Reference will be made to embodiments of the invention, examples of which may be illustrated in the accompanying figures. These figures are intended to be illustrative, not limiting. Although the invention is generally described in the context of these embodiments, it should be understood that it is not intended to limit the scope of the invention to these particular embodiments.

FIG. (“FIG.”) 1 illustrates an operation of high-speed data-transfer between a memory and a memory controller.

FIG. 2 illustrates various modules that are involved in dynamic calibration of DDR controller according to various embodiments of the invention.

FIG. 3 is a flowchart for dynamically calibrating a DDR controller according to various embodiments of the invention according to various embodiments of the invention.

### DETAILED DESCRIPTION OF THE PREFERRED EMBODIMENTS

A system, device and method are described that provide dynamic calibration of high-speed systems, such as high-speed DDR memory systems. In accordance with certain embodiments of the invention, a DDR controller includes functionality that both initializes settings associated with a data window and dynamically maintains the data window within a defined threshold of operation. In various embodiments, an initial calibration module is provided on the DDR controller for performing a full calibration wherein a data window is initially generated and a center point of the data window is established within a specified threshold. Interrupts may be generated to evaluate the data window and center point and/or recalibrate the data window and center point in response to the evaluation or an interrupt generated from another source, such as a system error or user generated interrupt.

In the following description, for purpose of explanation, specific details are set forth in order to provide an understanding of the invention. It will be apparent, however, to one skilled in the art that the invention may be practiced without these details. One skilled in the art will recognize that embodiments of the present invention, some of which are described below, may be incorporated into a number of different systems and devices. The embodiments of the present invention may also be present in software, hardware or firmware. Structures and devices shown below in block diagram are illustrative of exemplary embodiments of the invention and are meant to avoid obscuring the invention. Furthermore, connections between components and/or modules within the figures are not intended to be limited to direct connections. Rather, data between these components and modules may be modified, re-formatted or otherwise changed by intermediary components and modules.

Reference in the specification to “one embodiment” or “an embodiment” means that a particular feature, structure, characteristic, or function described in connection with the embodiment is included in at least one embodiment of the invention. The appearances of the phrase “in one embodiment” in various places in the specification are not necessarily all referring to the same embodiment.

### A. Overview

In various embodiments of the invention, an initial relationship between one or more synchronization clocks and a data window is set and the phase relationship between the synchronization clock and data window across voltage and temperature variations is constantly maintained. An initial calibration module is provided on a DDR controller for performing a full calibration of high-speed memory systems, such as DDR systems, wherein the data window is determined and a corresponding center point of the data window is established within a specified threshold.

FIG. 1 illustrates a typical operation of high-speed data-transfer 103 between a memory 101 and a controller 102. The controller 102 provides an internal counter or clock (not shown) that handles timing parameters of the data transfer or the read and write operations that take place between the memory 101 and the controller 102. An example of the memory 101 and the controller 102 would be a DDR memory and a DDR controller.

According to various embodiments of the invention, an operation generally begins with an active command followed by a READ/WRITE command. Each command may be registered at positive edge of the clock. A bidirectional data strobe (DQS pulse or window) may be transmitted along with the data. The DQS signal may be used to capture data at the receiver. For example, the DQS may be transmitted by the memory during read operation and/or the DQS may be transmitted by the controller during write operation. The DQS is generally edge aligned with data for read operations and center aligned with data for write operations, but this may vary across different memory systems. The data is generally captured at the receiver at a valid data window, which is a time window per output byte when data is valid to read.

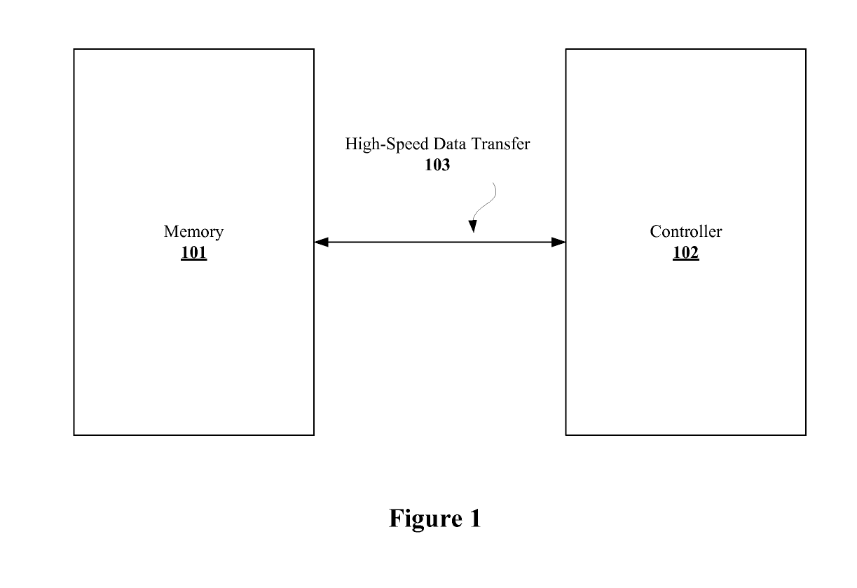

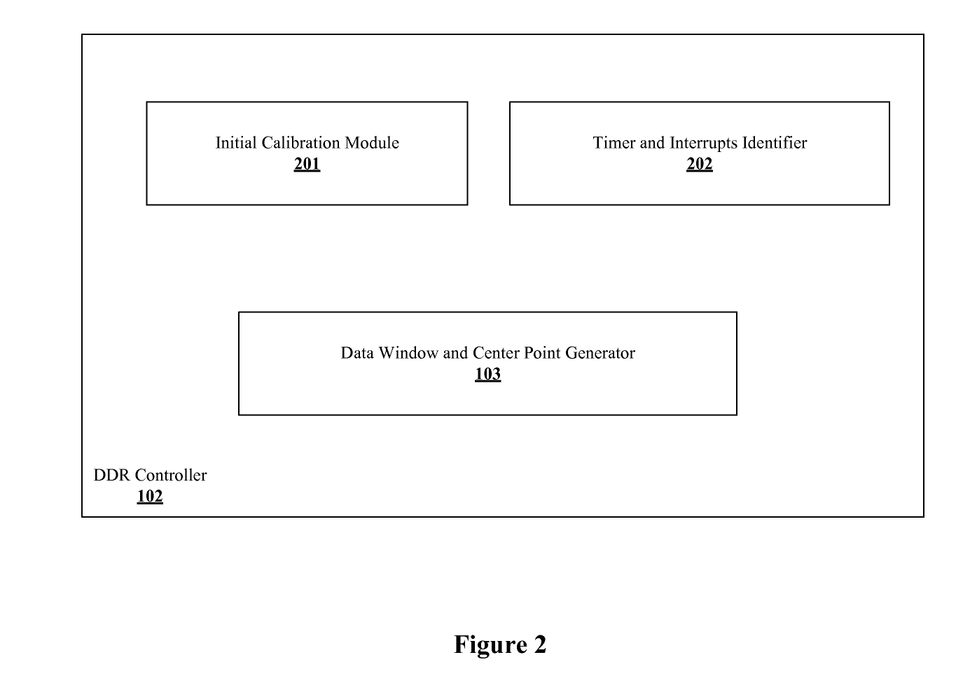

FIG. 2 illustrates various modules that are involved in dynamic calibration of DDR controller according to various embodiments of the invention. As previously explained, an initial calibration module 201 is provided on a DDR controller 102 for performing a full calibration of a memory 101. The full calibration sequence may be performed on the controller 102 at “start of a day” initialization or other initialization event of the controller 102. The full calibration of the DDR controller may comprise a standard DDR initialization sequence and a write/read/compare routine, which are well understood by one of skill in the art. A standard DDR initialization sequence may include setting up standard parameters (such as strobe signal ‘DQS’) at startup. In prior art systems previously described, a number of configuration settings are calculated at “start of a day” initialization and used throughout the day until the system is turned off.

The standard DDR initialization sequence oftentimes includes a plurality of write/read/compare routines to determine an optimal data window and center point. These routines may be performed on a certain memory range while varying all allowable configuration settings in the controller. For example, the write/read/compare routine may be performed by generating ‘test’ patterns, processing the test patterns within a memory system, and reading/comparing the test patterns in accordance to the configuration settings of the memory. A pass/fail type rating is designated to each tested setting and a frequency of failure is tracked.

The collection of passed settings is used to create an optimal data window and locate a center point therein. In particular, certain routines may be used to calculate the data window and determine the best-case center point to use in configuring and operating the DDR memory controller. In various embodiments of the invention, the data window and the center point are established within a specified threshold set relative to the memory system. The optimal configuration settings may be saved to non-volatile memory along with a log of the data eye abstraction. At this point, the DDR controller is considered initialized and operational.

At some point after the controller 102 is ready for operation, a timer is started. In accordance with certain embodiments of the invention, the timer is located on the controller 102 and communicates with a timer and interrupts identifier module 202. In various embodiments of the invention, the timer may be a decreasing counter that expires to a zero count after certain number of counts or programmed amount of time expires. Once this time period expires, the counter generates a timer expiration interrupt.

In certain embodiments of the invention, the timer and interrupts identifier module 202 checks for any interrupts at the memory at certain intervals, such as at every time count. The interrupts may be either an error-condition interrupt or the timer expiration interrupt. The error-conditioned interrupt may include feedback from a temperature sensor, voltage sensor, user intervention or other trigger. For example, the feedback signal from the temperature sensor may indicate a temperature deviation from an optimum range of temperature required for DDR operation. When the temperature of the DDR memory increases beyond the optimum range, errors may occur and the DDR system's data transfer may not operate efficiently. Thus, re-calibration of the DDR controller becomes essential.

If an error-condition interrupt (such as temperature feedback or human intervention) occurs, the calibration sequence is repeated resulting in the initial calibration module 201 performing the above-explained full calibration procedure. This ensures the dynamic calibration of the DDR controller when an error occurs.

If the timer expiration interrupt occurs, the data window and its center point are re-evaluated. The timer expiration interrupt occurs when a pre-defined amount of time expires. This expiration of the timer generates an interrupt for the timer and interrupts identifier module 202 to allow it to re-examine the current configuration settings. As previously discussed, if certain criteria are met, then a full calibration or re-calibration occurs to adjust the data window and center point. This ensures that proper calibration of the DDR system is consistently maintained over time.

In various embodiments of the invention, the controller 102 also contains a data window and center point generator 203 for generating a new data window and establishing its center point in response to an interrupt. Basically, the data window and center point generator 203 determines if the current data eye window and center point that were established during the full calibration of DDR memory system, are still within the specified threshold.

If a current data window and center point are found acceptable within the preferred threshold, then the timer and interrupts identifier module 202 again waits for the timer to expire and repeats this check. If the threshold is violated, then the data window and center point generator 203 generates a new data window and establishes its center point, and replaces the same with the current settings in the memory. In various embodiments of the invention, DDR configuration settings are readjusted to the newly determined suitable settings. Operations and data associated with this analysis and re-calibration may be saved within a memory device and logged.

### B. Dynamic DDR Calibration Operation Illustration

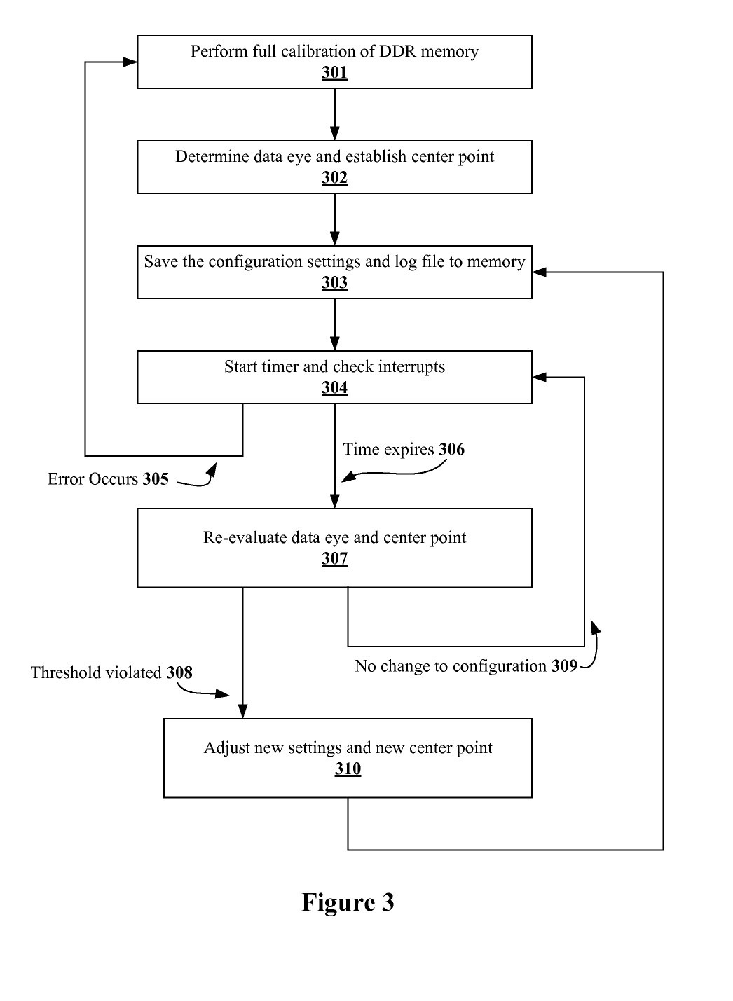

FIG. 3 illustrates an exemplary method of dynamically calibrating a DDR controller according to various embodiments of the invention. Initially, a full calibration of DDR memory may be performed at the “start of a day” initialization of the DDR controller 301. Apart from the standard DDR initialization sequence, the full calibration of the DDR memory also performs a write/read/compare routine by writing a ‘test’ pattern and reading/comparing this ‘test’ pattern to configuration settings of the memory in order to identify, track and collect pass and fail conditions of the memory system.

The collection of passed setting is used to create an optimal data window and corresponding center point 302. Once the data window and the center point are established, the configuration settings for the same is saved and logged into the memory 303. According to various embodiments of the invention, the data window and the center point are established within a specified threshold. At this point the DDR controller is considered operational.

Thereafter, a timer is started and interrupts are checked 304 as the timer counts down. The interrupts may be either an error-condition interrupt or the timer expiration interrupt. If an error-condition interrupt occurs 305, the calibration sequence (as explained in steps 301 to 304) is repeated and the above explained full calibration process of the DDR memory is performed. If a timer expiration interrupt occurs 306, the data window and its center point are re-evaluated 307. If the current data window and center point (as established in step 302) fall within a preferred range or threshold 309, then the timer is restarted to recheck for any further interrupts 304.

A new data window and center point are recalculated 310 if violation of the specified threshold occurs 308. The new data window and its center point are replaced with the current settings in the memory by saving off new settings and logging information regarding the same in the memory 303.

The embodiments of the invention as described above provides flexibility on a per DDR memory controller basis. For example, if some configurable features available on one controller are not available, the configuration settings may be easily modified on the another.

While the present invention has been described with reference to certain exemplary embodiments, those skilled in the art will recognize that various modifications may be provided. Accordingly, the scope of the invention is to be limited only by the following claims.

We claim:

1. A method for dynamically maintaining a data window and center point in a high-speed memory system, the method comprising:
performing a first calibration procedure in which system settings are established that generate the data window and center point within a preferred range;
initiating a timer that generates a first interrupt after a pre-defined time period expires;
receiving the first interrupt and stopping read/write operations within the high-speed memory system;
analyzing the data window and center point to determine whether the data window and center point are operating within the preferred range;
if the data window or center point are outside the preferred range, performing a second calibration procedure to adjust the data window and center point so that the data window and center point are operating within the preferred range; and
starting read/write operations within the high-speed memory system using the adjusted data window and center point.

2. The method of claim 1 further comprising the step of receiving an error-interrupt and initiating a third calibration procedure to adjust the data window and center point so that both are operating within the preferred range.

3. The method of claim 2 wherein the error-interrupt is received from a temperature sensor.

4. The method of claim 2 wherein the error-interrupt is received from a voltage sensor.

5. The method of claim 2 wherein the error-interrupt is initiated by a user in response to a trigger.

6. The method of claim 1 further comprising the step of storing information related to the first calibration procedure in a memory.

7. The method of claim 1 wherein the first calibration procedure comprises analyzing a plurality of test patterns and associated settings to identify a preferred set of settings that result in the data window and center point operating within the preferred range.

8. The method of claim 7 wherein an associate pass/fail condition is associated with each of the test patterns and associated settings within the plurality.

9. The method of claim 1 wherein the high-speed memory system is a dual data rate memory system.

10. The method of claim 9 wherein the dual data rate memory system is a dual data rate static random access memory system.

11. A dual data rate (“DDR”) controller comprising:
an initial calibration module that performs a full calibration on a DDR memory system in which the DDR controller resides and generates a first plurality of control settings that result in a first data window and center point;
a timer and interrupts identifier that receives a plurality of interrupts and causes read/write operations within the DDR memory system to pause; and
a data window and center point generator that adjusts the first data window and center point so that both fall within a preferred threshold range in response to an interrupt being received by the timer and interrupts identifier.

12. The controller of claim 11 further comprising a counter that defines a period of time in which time interrupts are generated so that the data window and center point may be analyzed relative to the preferred threshold range.

13. The controller of claim 12 wherein the timer and interrupts identifier receives a time interrupt from the counter and pauses read/write operations within the DDR memory system.

14. The controller of claim 13 wherein the timer and interrupts identifier analyzes the first data window and center point relative to the preferred threshold range to determine whether the data window and center point generator should adjust the first data window and center point.

15. The controller of claim 11 wherein the timer and interrupts identifier receives an error-interrupt and causes read/write operations within the DDR memory system to pause to allow the data window and center point generator to adjust the first data window and center point.

16. The controller of claim 11 wherein information generated from the timer and interrupts identifier and the data window and center point generator are stored within a memory device.

17. The controller of claim 11 wherein the DDR memory system is a DDR SRAM memory system.

18. A computer program product embodied on a computer readable medium for dynamically maintaining a data window and center point in a high-speed memory system, the computer program product comprising computer instructions for:
performing a first calibration procedure in which system settings are established that generate the data window and center point within a preferred range;
initiating a timer that generates a first interrupt after a pre-defined time period expires;
receiving the first interrupt and stopping read/write operations within the high-speed memory system;
analyzing the data window and center point to determine whether the data window and center point are operating within the preferred range;
if the data window or center point are outside the preferred range, performing a second calibration procedure to adjust the data window and center point so that the data window and center point are operating within the preferred range; and
starting read/write operations within the high-speed memory system using the adjusted data window and center point.

19. The computer program product of claim 18 further comprising computer instructions for receiving an error-interrupt and initiating a third calibration procedure to adjust the data window and center point so that both are operating within the preferred range.

20. The computer program product of claim 18 wherein the first calibration procedure comprises analyzing a plurality of test patterns and associated settings to identify a preferred set of settings that result in the data window and center point operating within the preferred range.
